(19) United States
(12) Patent Application Publication
(10) Pub. No.: US 2025/0089424 A1
(43) Pub. Date: Mar. 13, 2025

(54) DISPLAY APPARATUS AND MANUFACTURING METHOD THEREOF

(71) Applicant: AUO Corporation, Hsinchu (TW)

(72) Inventors: Rong-Sheng Tsai, Hsinchu (TW); Wen-Jen Li, Hsinchu (TW); Shu-Jiang Liu, Hsinchu (TW)

(73) Assignee: AUO Corporation, Hsinchu (TW)

(21) Appl. No.: 18/768,025

(22) Filed: Jul. 10, 2024

(30) Foreign Application Priority Data
Sep. 8, 2023 (TW) 112134190

(51) Int. Cl. H01L 33/62; H01L 25/075; H01L 33/00; H01L 33/60

(52) U.S. Cl. CPC H10H 20/857; H01L 25/0753; H01L 25/167; H10H 20/01; H10H 20/856; H10H 20/0363

(57) ABSTRACT

A display apparatus includes a driving backplane, a transparent metal oxide pattern layer, light-emitting elements and transparent structures. The transparent metal oxide pattern layer has a solid portion and openings defined by the solid portion. The light-emitting elements are respectively located in the openings of the transparent metal oxide pattern layer. The transparent structures respectively cover the light emitting elements, respectively overlap the openings of the transparent metal oxide pattern layer, and expose electrodes of the light emitting elements. The transparent structures are located between the light emitting elements and the driving backplane. Moreover, a manufacturing method of the display apparatus is also provided.

### CROSS-REFERENCE TO RELATED APPLICATION

This application claims the priority benefit of Taiwan application serial no. 112134190, filed on Sep. 8, 2023. The entirety of the above-mentioned patent application is hereby incorporated by reference herein and made a part of this specification.

### BACKGROUND

### Technical Field

The disclosure relates to an optoelectronic device and a manufacturing method thereof, and in particular, to a display apparatus and a manufacturing method thereof.

### Description of Related Art

A light-emitting diode display panel includes a driving backplane and a plurality of light-emitting diode elements transferred onto the driving backplane. Inheriting the characteristics of light-emitting diodes, the light-emitting diode display panel has advantages of power saving, high efficiency, high brightness, and fast response time. In addition, compared with an organic light-emitting diode display panel, the light-emitting diode display panel further has advantages of easy color adjustment, long light emission life, no image burn-in, etc. Therefore, the light-emitting diode display panel is considered as a display technology of the next generation.

In the manufacturing process of the light-emitting diode display panel, the light-emitting diodes on the growth substrate must be transferred to the first adhesive layer of the first temporary storage substrate, and the light-emitting diodes on the first adhesive layer of the first temporary storage substrate must be transferred to the second adhesive layer of the second temporary storage substrate, and then the light-emitting diodes on the second adhesive layer of the second temporary storage substrate is transferred to the driving backplane and the light-emitting diodes is electrically connected to the driving backplane. When the light-emitting diode located on the first adhesive layer of the first temporary storage substrate is transferred to the second adhesive layer of the second temporary storage substrate, a portion of the first adhesive layer remains on the light-emitting diode. When removing the portion of the first adhesive layer remaining on the light-emitting diodes, the etching gas used to remove the remaining portion of the first adhesive layer will damage the second adhesive layer of the second temporary storage substrate, causing cracking phenomenon in the second adhesive layer. The light-emitting diodes disposed in the cracked second adhesive layer will deviate from the normal position, which will lead to poor connection with the driving backplane and reduce the manufacturing yield of the light-emitting diode display panel.

### SUMMARY

The disclosure provides a display apparatus with high manufacturing yield.

The disclosure provides a manufacturing method of the display apparatus, which can improve the manufacturing yield.

The display apparatus of the disclosure includes a driving backplane, a transparent metal oxide pattern layer, light-emitting elements and transparent structures. The transparent metal oxide pattern layer has a solid portion and openings defined by the solid portion. The light-emitting elements are respectively located in the openings of the transparent metal oxide pattern layer, wherein electrodes of the light-emitting elements are bonded to the driving backplane. The transparent structures respectively cover the light-emitting elements, respectively overlap with the openings of the transparent metal oxide pattern layer, and expose the electrodes of the light-emitting elements. The transparent structures are located between the light-emitting elements and the driving backplane.

The manufacturing method of the display apparatus of the disclosure includes the following steps: providing a light-emitting element substrate, wherein the light-emitting element substrate includes a temporary base, an adhesive layer, light-emitting elements and adhesive patterns, and the adhesive layer is disposed on the temporary base, the light-emitting elements are disposed on the adhesive layer, and the adhesive patterns are respectively disposed on the light-emitting elements; forming a transparent metal oxide layer on the temporary base to cover the adhesive layer, the light-emitting elements and the adhesive patterns; patterning the transparent metal oxide layer to form a transparent metal oxide pattern layer, wherein a solid portion of the transparent metal oxide pattern layer covers a portion of the adhesive layer, and openings of the transparent metal oxide pattern layer respectively expose the adhesive patterns; in a condition where the solid portion of the transparent metal oxide pattern layer covers the portion of the adhesive layer, removing the adhesive patterns on the light-emitting elements to expose the electrodes of the light-emitting elements respectively located in the openings of the transparent metal oxide pattern layer; forming transparent structures respectively on the light-emitting elements, wherein the transparent structures respectively cover the light-emitting elements, respectively overlap the openings of the transparent metal oxide pattern layer and expose the electrodes of the light-emitting elements, a light-emitting element array structure comprises the transparent metal oxide pattern layer, the light-emitting elements and the transparent structures; separating at least one portion of the light-emitting element array structure and at least one portion of the adhesive layer; and bonding the light-emitting element array structure to a driving backplane, wherein the electrodes of the light-emitting elements are electrically connected to the driving backplane.

### BRIEF DESCRIPTION OF THE DRAWINGS

FIG. 1A to FIG. 1K are schematic cross-sectional views of the manufacturing process of the display apparatus according to an embodiment of the disclosure.

FIG. 2 is a schematic top view of a display apparatus according to an embodiment of the disclosure.

FIG. 3A to FIG. 3K are schematic cross-sectional views of the manufacturing process of the display apparatus according to an embodiment of the disclosure.

FIG. 4 is a schematic top view of a display apparatus according to an embodiment of the disclosure.

### DESCRIPTION OF THE EMBODIMENTS

Reference will now be made in detail to exemplary embodiments provided in the disclosure, examples of which are illustrated in accompanying drawings. Wherever possible, identical reference numerals are used in the drawings and descriptions to refer to identical or similar parts.

It should be understood that when a device such as a layer, film, region or substrate is referred to as being “on” or “connected to” another device, it may be directly on or connected to another device, or intervening devices may also be present. In contrast, when a device is referred to as being “directly on” or “directly connected to” another device, there are no intervening devices present. As used herein, the term “connected” may refer to physical connection and/or electrical connection. Besides, if two devices are “electrically connected” or “coupled”, it is possible that other devices are present between these two devices.

The term “about,” “approximately,” or “substantially” as used herein is inclusive of the stated value and a mean within an acceptable range of deviation for the particular value as determined by people having ordinary skill in the art, considering the measurement in question and the error associated with measurement of the particular quantity (i.e., the limitations of the measurement system). For example, “about” may mean within one or more standard deviations, for example, ±30%, ±20%, ±10%, or ±5% of the stated value. Moreover, a relatively acceptable range of deviation or standard deviation may be chosen for the term “about,” “approximately,” or “substantially” as used herein based on optical properties, etching properties or other properties, instead of applying one standard deviation across all the properties.

Unless otherwise defined, all terms (including technical and scientific terms) used herein have the same meaning as commonly understood by people of ordinary skill in the art. It will be further understood that terms, such as those defined in the commonly used dictionaries, should be interpreted as having a meaning that is consistent with their meaning in the context of the relevant art and the invention and will not be interpreted in an idealized or overly formal sense unless expressly so defined herein.

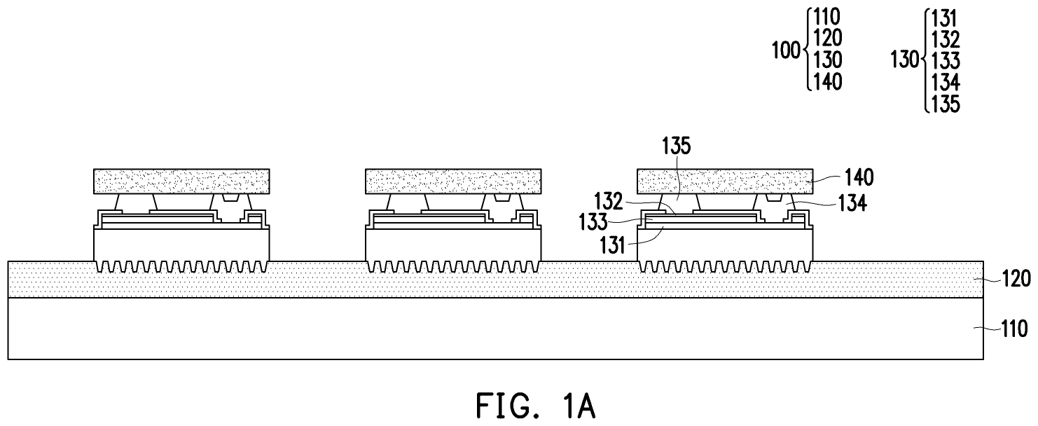

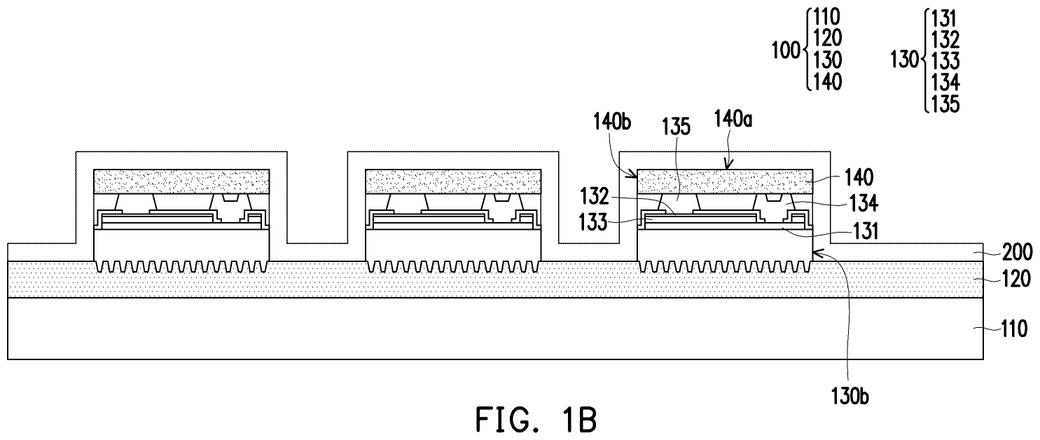

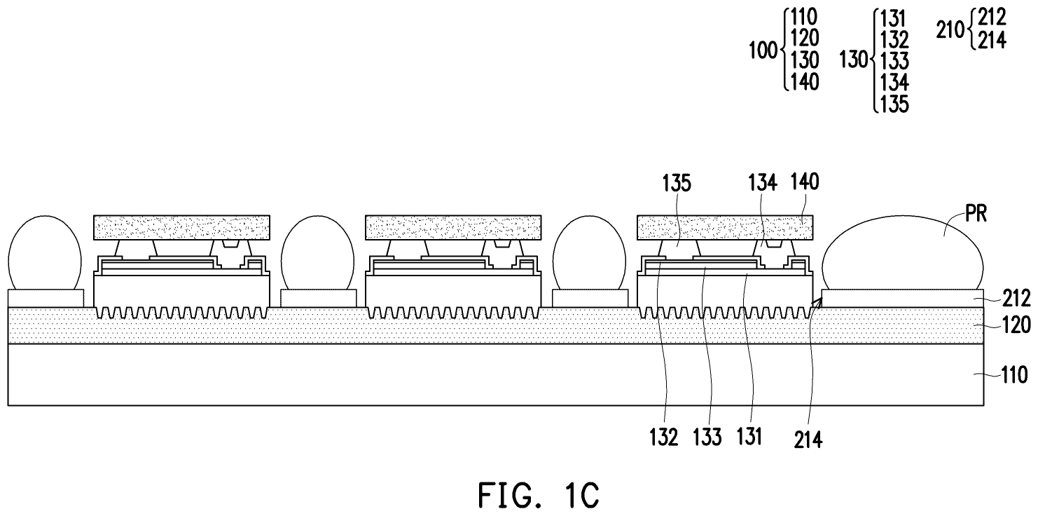

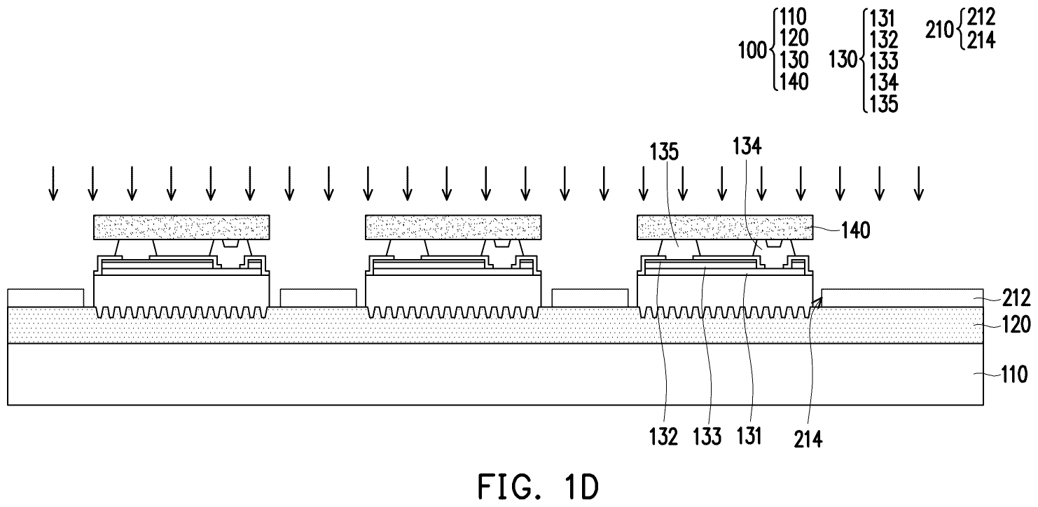

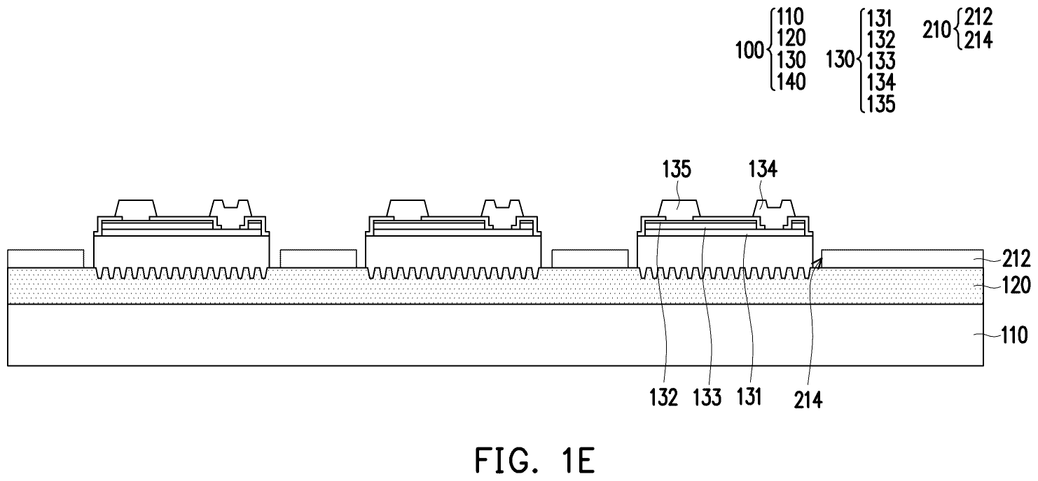

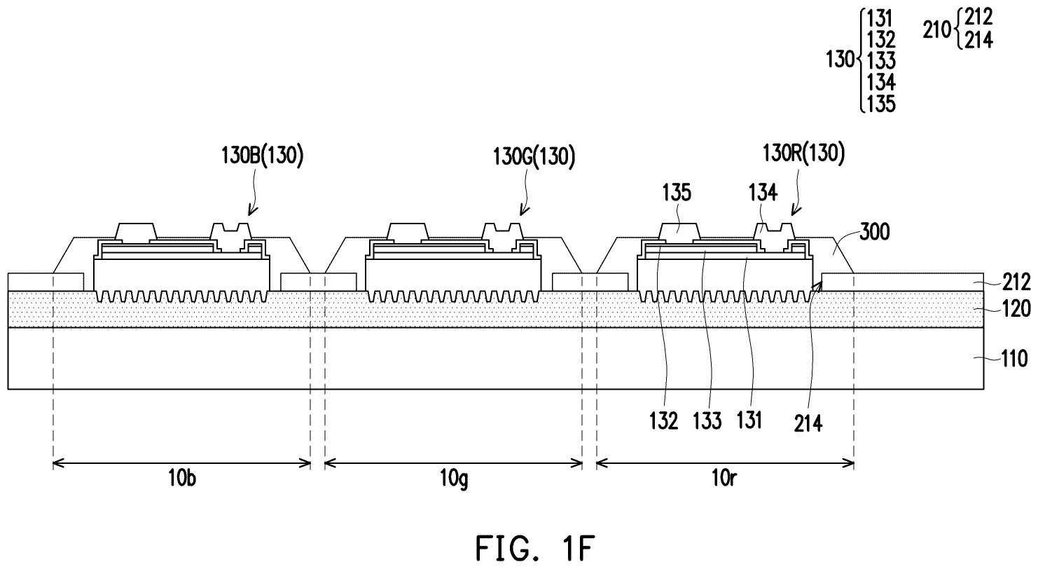

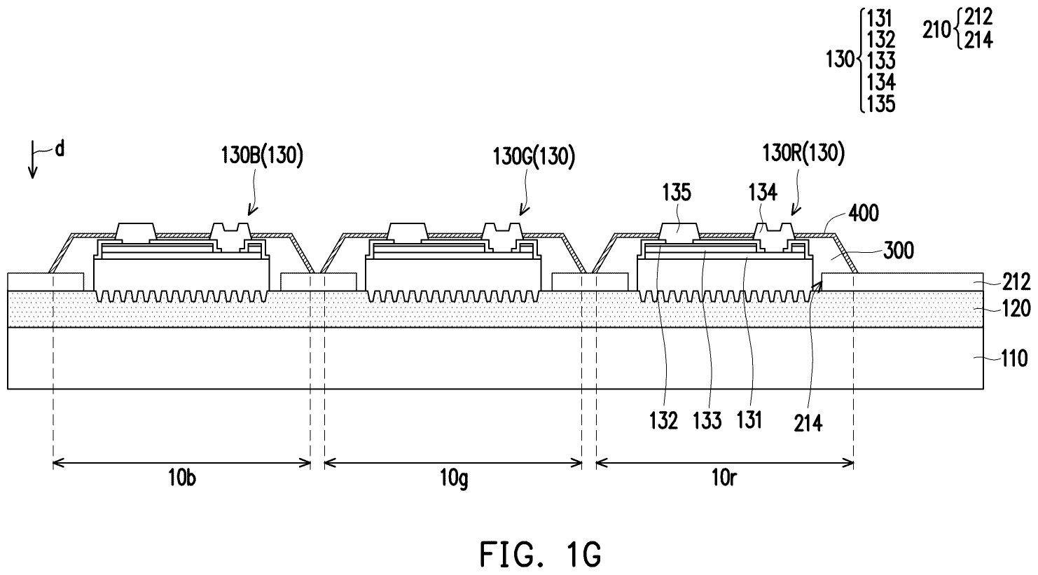

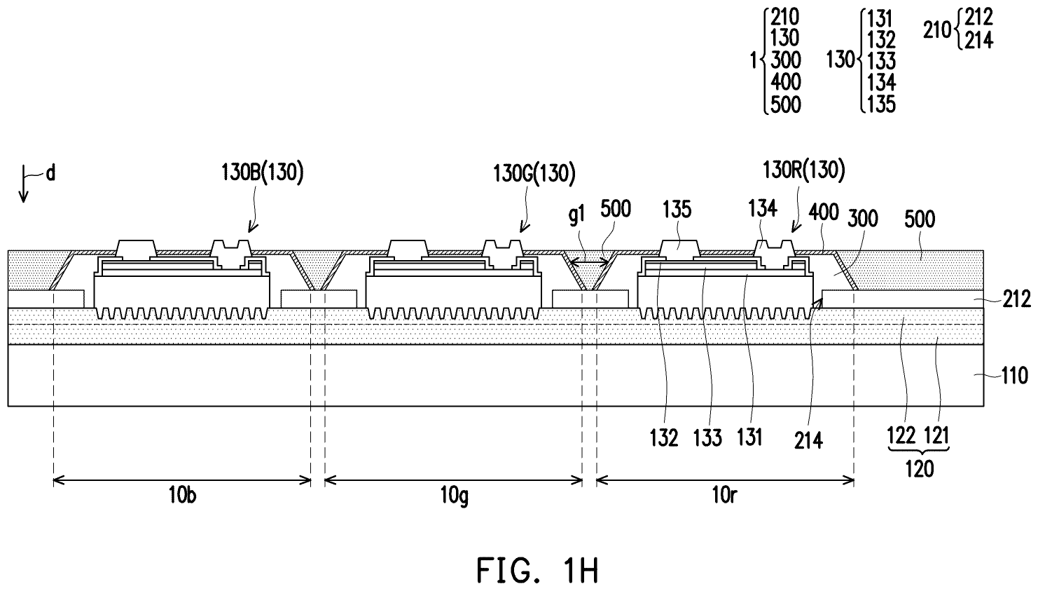

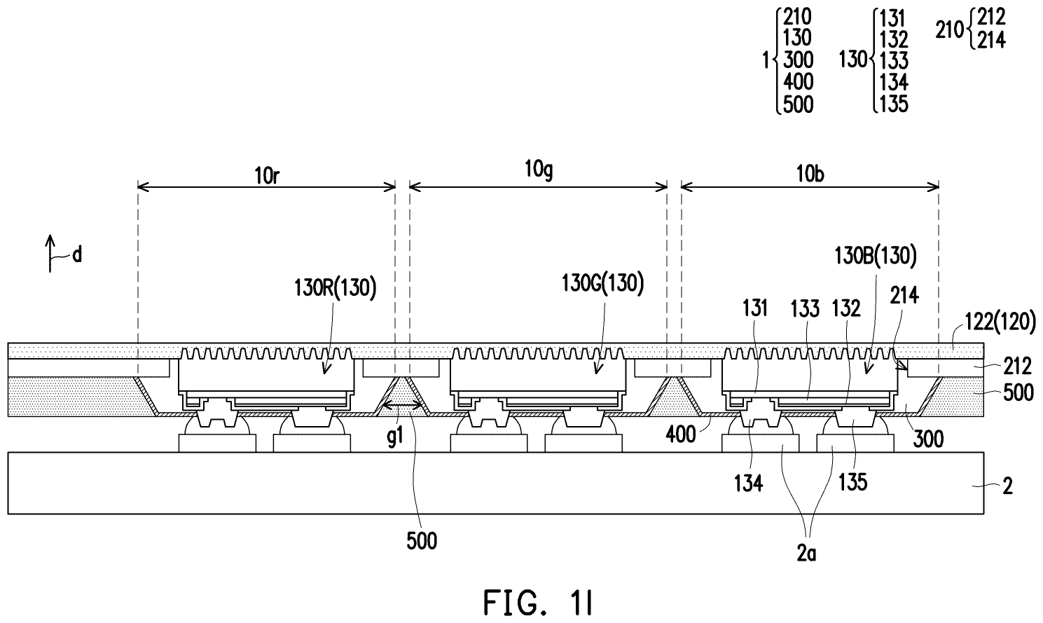

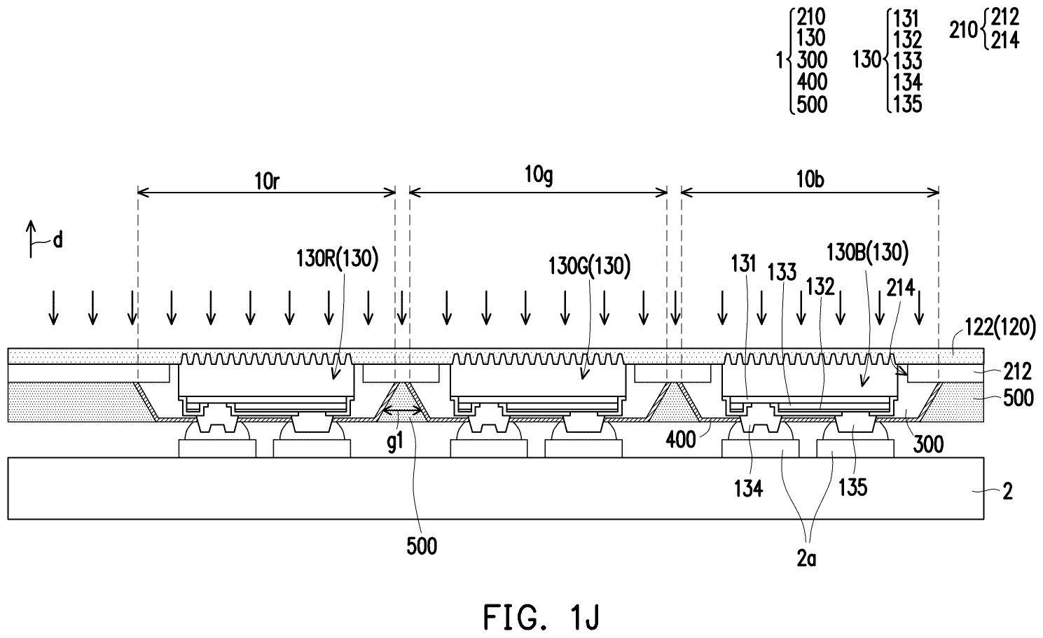

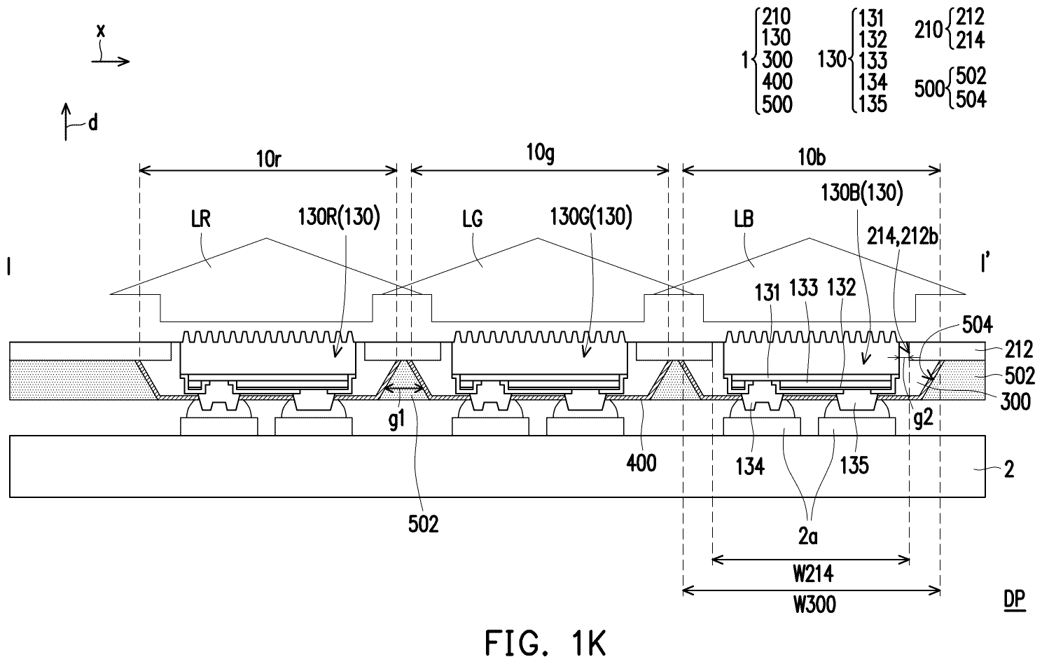

FIG. 1A to FIG. 1K are schematic cross-sectional views of the manufacturing process of the display apparatus according to an embodiment of the disclosure.

Please refer to FIG. 1A. First, a light-emitting element substrate 100 is provided. The light-emitting element substrate 100 includes a temporary base 110, an adhesive layer 120, light-emitting elements 130 and adhesive patterns 140. The adhesive layer 120 is disposed on the temporary base 110, the light-emitting elements 130 are disposed on the adhesive layer 120, and the adhesive patterns 140 are disposed on the light-emitting elements 130 respectively. The light-emitting elements 130 are located between the adhesive patterns 140 and the adhesive layer 120.

In one embodiment, the light-emitting element 130 may include a first semiconductor layer 131, a second semiconductor layer 132, an active layer 133 disposed between the first semiconductor layer 131 and the second semiconductor layer 132, and the first electrode 134 and the second electrode 135 electrically connected to the first semiconductor layer 131 and the second semiconductor layer 132, respectively. In one embodiment, the first electrode 134 and the second electrode 135 of the light-emitting element 130 may be selectively located on the same side of the active layer 133. In the other word, the light-emitting element 130 may selectively be a horizontal micro-light-emitting diode (lateral μLED), but the disclosure is not limited thereto. In one embodiment, the active layer 133 of the light-emitting element 130 may be selectively located between the temporary base 110 and the first electrode 134 of the light-emitting element 130 and between the temporary base 110 and the second electrode 135 of the light-emitting element 130, but the disclosure does not limited thereto.

Please refer to FIG. 1B. Next, a transparent metal oxide layer 200 is formed on the temporary base 110 to cover the adhesive layer 120, the light-emitting elements 130 and the adhesive patterns 140. Specifically, in one embodiment, the transparent metal oxide layer 200 may cover all areas of the adhesive layer 120 not occupied by the light-emitting elements 130, the sidewalls 130b of the light-emitting elements 130, and the top surfaces 140a of the adhesive patterns 140 facing away from the temporary base 110, and sidewalls 140b of adhesive patterns 140. For example, in one embodiment, the transparent metal oxide layer 200 may be made of indium tin oxide, indium zinc oxide, aluminum tin oxide, aluminum zinc oxide, indium germanium zinc oxide, or other suitable oxides, or a stacked layer of at least two of the above.

Please refer to FIG. 1B and FIG. 1C. Then, the transparent metal oxide layer 200 is patterned to form a transparent metal oxide pattern layer 210, wherein solid portion 212 of the transparent metal oxide pattern layer 210 covers a part of the adhesive layer 120, and the openings 214 of the transparent metal oxide pattern layer 210 respectively expose the adhesive patterns 140. Specifically, in one embodiment, a photoresist pattern PR may be formed on the transparent metal oxide layer 200, wherein the photoresist pattern PR covers areas of the transparent metal oxide layer 200 that do not overlap with the adhesive patterns 140 and exposes the adhesive patterns 140; then, the transparent metal oxide layer 200 is etched using the photoresist pattern PR as a mask to form a transparent metal oxide pattern layer 210. Please refer to FIG. 1C. In one embodiment, the solid portion 212 of the transparent metal oxide pattern layer 210 may cover all areas of the adhesive layer 120 that are not occupied by the light-emitting elements 130, and the openings 214 of the transparent metal oxide pattern layer 210 respectively expose the adhesive patterns 140 and the light-emitting elements 130.

Please refer to FIG. 1D and FIG. 1E. Next, in the condition where the solid portion 212 of the transparent metal oxide pattern layer 210 covers a part of the adhesive layer 120, the adhesive patterns 140 on the light-emitting elements 130 are removed to expose electrodes of the light-emitting elements 130 respectively located in the openings 214 of the transparent metal oxide pattern layer 210. For example, in one embodiment, SF₆ and O₂ can be used as etching gases to remove the adhesive patterns 140, but the disclosure is not limited thereto. In one embodiment, after removing the adhesive patterns 140, the first electrode 134 and the second electrode 135 of each of the light-emitting elements 130 may be exposed, but the disclosure is not limited thereto.

Please refer to FIG. 1F. Next, transparent structures 300 are respectively formed on the light-emitting elements 130, wherein the transparent structures 300 respectively cover the light-emitting elements 130, respectively overlap with the openings 214 of the transparent metal oxide pattern layer 210, and expose electrodes of the light emitting elements 130. In one embodiment, each of the transparent structures 300 may expose the first electrode 134 and the second electrode 135 of a corresponding light-emitting element 130, but the disclosure is not limited thereto. In an embodiment, the material of the transparent structure 300 may be organic materials, inorganic materials or a combination thereof.

The transparent structures 300 define light-emitting areas 10r, 10g, and 10b. In one embodiment, the light-emitting elements 130 may include a first light-emitting element 130R, a second light-emitting element 130G and the third light-emitting element 130B respectively used to emit the first color light LR, the second color light LG and the third color light LB (refer to FIG. 1K), the light-emitting areas 10r, 10g, and 10b may include the first light-emitting area 10r, the second light-emitting area 10g, and the third light-emitting area 10b, and the first light-emitting element 130R, the second light-emitting element 130G, and the third light-emitting element 130B are respectively disposed in the first light-emitting area 10r, the second light-emitting area 10g and the third light-emitting area 10b. In one embodiment, the first color light LR, the second color light LG and the third color light LB (please refer to FIG. 1K) are, for example, red light, green light and blue light respectively, but the disclosure is not limited thereto.

Please refer to FIG. 1G. Next, reflective patterns 400 are respectively formed on the transparent structures 300, wherein the reflective patterns 400 are respectively disposed on the transparent structures 300 and expose electrodes of the light-emitting elements 130. In one embodiment, each of the reflective patterns 400 may expose the first electrode 134 and the second electrode 135 of a corresponding light-emitting element 130, but the disclosure is not limited thereto. The reflective patterns 400 define the light-emitting directions d of the light-emitting areas 10r, 10g, and 10b. In one embodiment, the light emitting direction d may be a direction from the active layer 133 of the light-emitting element 130 to the opening 214 of the transparent metal oxide pattern layer 210.

Please refer to FIG. 1H. Next, a light-shielding layer 500 is formed to cover the gaps g1 between the reflective patterns 400. The light-shielding layer 500 separates the light-emitting elements 130 and is used to increase contrast. The transparent metal oxide pattern layer 210, the light-emitting elements 130, the transparent structures 300, the reflective patterns 400 and the light-shielding layer 500 form a light-emitting element array structure.

Please refer to FIG. 1H and FIG. 1I. Next, the light-emitting element array structure 1 and at least a part of the adhesive layer 120 are separated. Specifically, in one embodiment, the adhesive layer 120 includes a first part 121 close to the temporary base 110 and a second part 122 close to the light-emitting element 130; the step of separating the light-emitting element array structure 1 and at least a part of the adhesive layer 120 may be: separating the light-emitting element array structure 1 and the first part 121 of the adhesive layer 120, wherein after the light-emitting element array structure 1 is separated from the first part 121 of the adhesive layer 120, the second part 122 of the adhesive layer 120 remains on the light-emitting elements 130 and the transparent metal oxide pattern layer 210 of the light-emitting element array structure 1. For example, in one embodiment, a laser lift off (LLO) process may be used to separate the light-emitting element array structure 1 and at least a part of the adhesive layer 120, but the disclosure is not limited thereto.

Please refer to FIG. 1I. Next, the light-emitting element array structure 1 and the driving backplane 2 are bonded, wherein electrodes of the light-emitting elements 130 of the light-emitting element array structure 1 (i.e., the first electrodes 134 and the second electrodes 135) is electrically connected to the driving backplane 2. For example, in one embodiment, the driving backplane 2 has pad groups 2a, and the first electrode 134 and the second electrode 135 of each of the light-emitting elements 130 may be respectively connected to the bonding pads of a corresponding pad group 2a, but the disclosure is not limited thereto.

Please refer to FIG. 1J and FIG. 1K, in one embodiment, in the condition where the transparent metal oxide pattern layer 210 shields the light-shielding layer 500, the second part 122 of the adhesive layer 120 remaining on the light-emitting element array structure 1 is removed. For example, in one embodiment, SF₆ and O₂ may be used as etching gases to remove the remaining second part 122 of the adhesive layer 120, but the disclosure is not limited thereto. At this point, the display apparatus DP of this embodiment is completed.

It is worth mentioning that, as shown in FIG. 1D and FIG. 1E, during the process of removing the adhesive patterns 140, the transparent metal oxide pattern layer 210 is used as a protective layer to protect the adhesive layer 120 below it, this makes the adhesive layer 120 less susceptible to the influence of etching gases and cause cracking. When the adhesive layer 120 is less prone to cracking, the success rate of transferring the light-emitting elements 130 from the temporary base 110 to the correct positions on the driving backplane 2 is greatly increased, thereby improving the manufacturing yield of the display apparatus DP. In addition, in one embodiment, after the light-emitting element array structure 1 is transferred from the temporary base 110 to the driving backplane 2, if a part of the adhesive layer 120 remains on the light-emitting element array structure 1 (as shown in FIG. 1J), during the process of removing the remaining part of the adhesive layer 120, the transparent metal oxide pattern layer 210 may be used as a protective layer again to protect the underlying components (such as but not limited to: light-shielding layer 500), thereby improving the reliability of display apparatus DP.

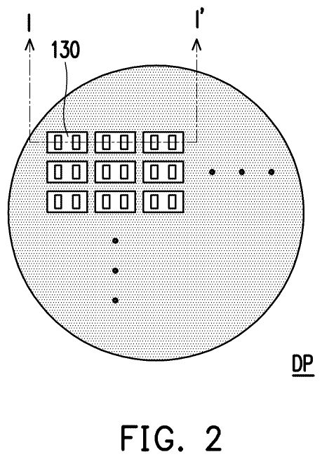

FIG. 2 is a schematic top view of a display apparatus according to an embodiment of the disclosure. FIG. 1K corresponds to the section line I-I′ of FIG. 2. Please refer to FIG. 1K and FIG. 2. The display apparatus DP includes a driving backplane 2 and a light-emitting element array structure 1 boned to the driving backplane 2. The light-emitting element array structure 1 includes the transparent metal oxide pattern layer 210, the light-emitting elements 130, the transparent structures 300, the reflective patterns 400 and the light-shielding layer 500.

The transparent metal oxide pattern layer 210 has a solid portion 212 and openings 214 defined by the solid portion 212. The light-emitting elements 130 are respectively located in the openings 214 of the transparent metal oxide pattern layer 210, wherein the electrodes (such as but not limited to: the first electrodes 134 and the second electrodes 135) of the light-emitting elements 130 are connected to the driving backplane 2. The transparent structures 300 respectively cover the light-emitting elements 130, respectively overlap the openings 214 of the transparent metal oxide pattern layer 210, and expose the electrodes of the light-emitting elements 130 (for example: the first electrodes 134 and the second electrode 135), wherein the transparent structures 300 are located between the light-emitting elements 130 and the driving backplane 2. The reflective patterns 400 are respectively disposed on the transparent structures 300 and expose electrodes of the light-emitting elements 130 (for example, but not limited to: the first electrodes 134 and the second electrodes 135), wherein the reflective patterns 400 is located between the transparent structures 300 and the driving backplane 2. The light-shielding layer 500 covers the gaps g1 between the reflective patterns 400. The light-shielding layer 500 is located between the transparent metal oxide pattern layer 210 and the driving backplane 2.

In one embodiment, the solid portion 212 of the transparent metal oxide pattern layer 210 has sidewalls 212b defining the openings 214, gaps g2 exist between the light-emitting elements 130 and the sidewalls 212b, and the transparent structures 300 fill in the gaps g2.

In one embodiment, a maximum dimension W300 of each of the transparent structure 300 in a direction x substantially parallel to the driving backplane 2 is larger than a dimension W214 of an opening 214 of the corresponding transparent metal oxide pattern layer 210 in the same direction x. In one embodiment, each of the reflective patterns 400 at least partially overlaps an opening 214 of the corresponding transparent metal oxide pattern 210.

In one embodiment, in addition to being located between the solid portion 212 of the transparent metal oxide pattern layer 210 and the driving backplane 2, the light-shielding layer 500 is also located between the reflective patterns 400 and the driving backplane 2. In one embodiment, the solid portion 502 of the light-shielding layer 500 overlaps the solid portion 212 of the transparent metal oxide pattern layer 210. In one embodiment, the openings 504 of the light-shielding layer 500 respectively overlap with the openings 214 of the transparent metal oxide pattern layer 210.

It must be noted here that the following embodiments follow the component numbers and part of the content of the previous embodiments, wherein the same numbers are used to represent the same or similar elements, and descriptions of the same technical content are omitted. For descriptions of omitted parts, please refer to the foregoing embodiments and will not be repeated in the following embodiments.

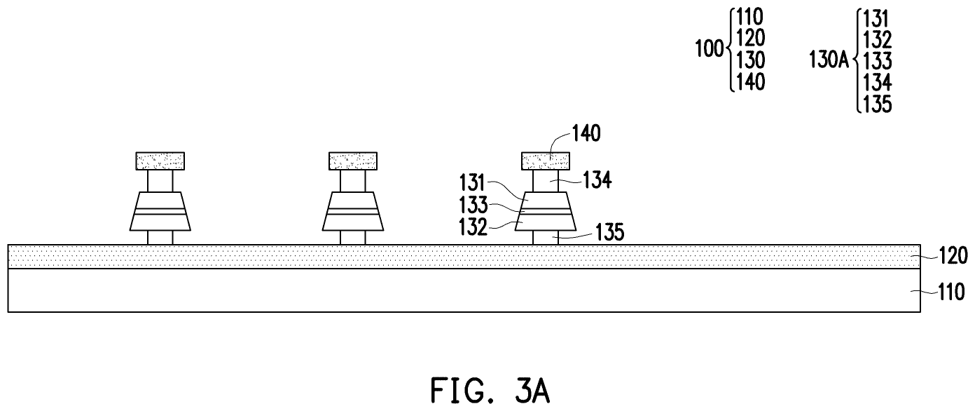

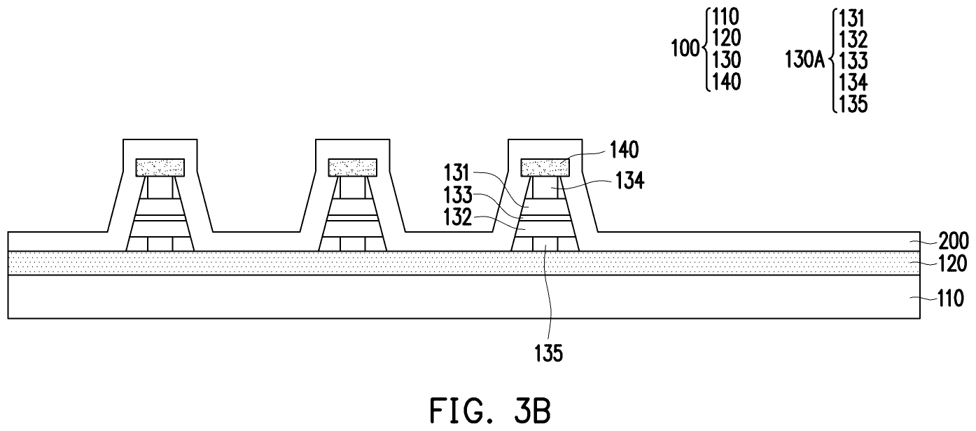

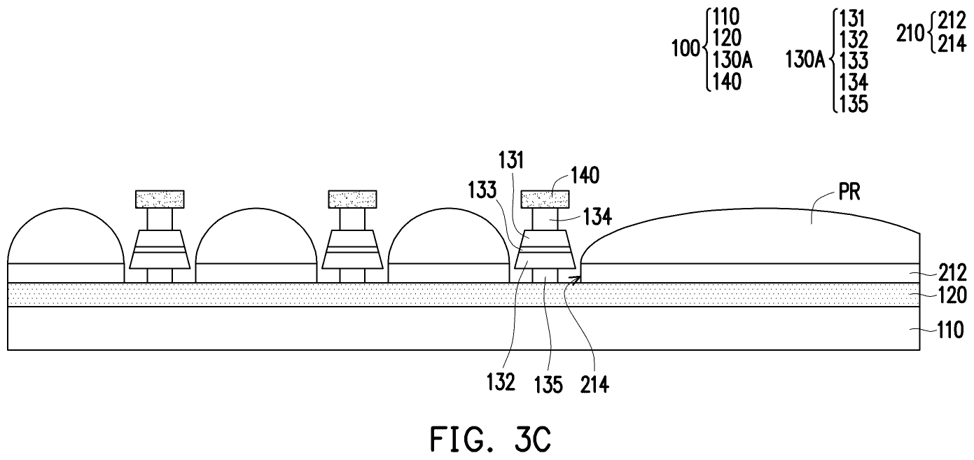

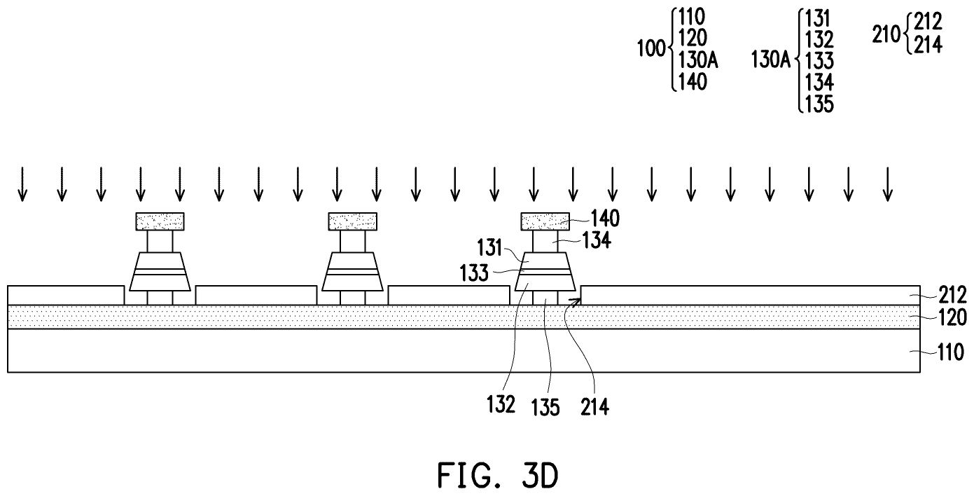

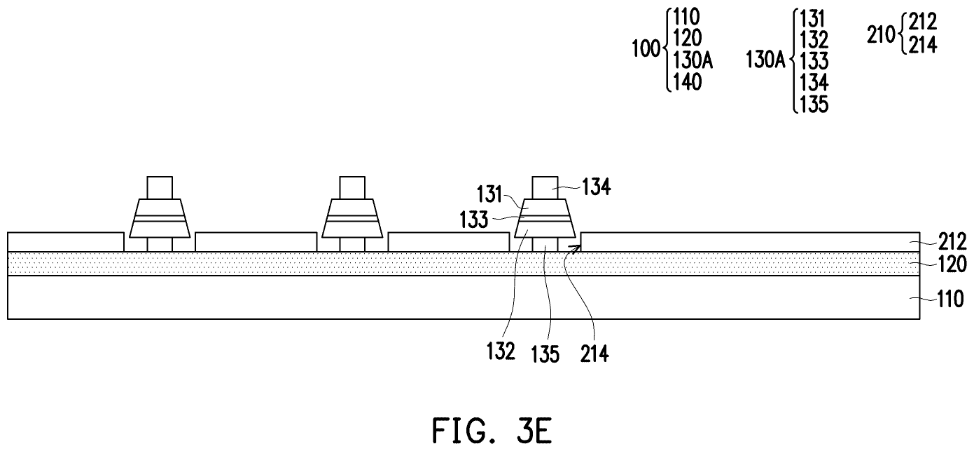

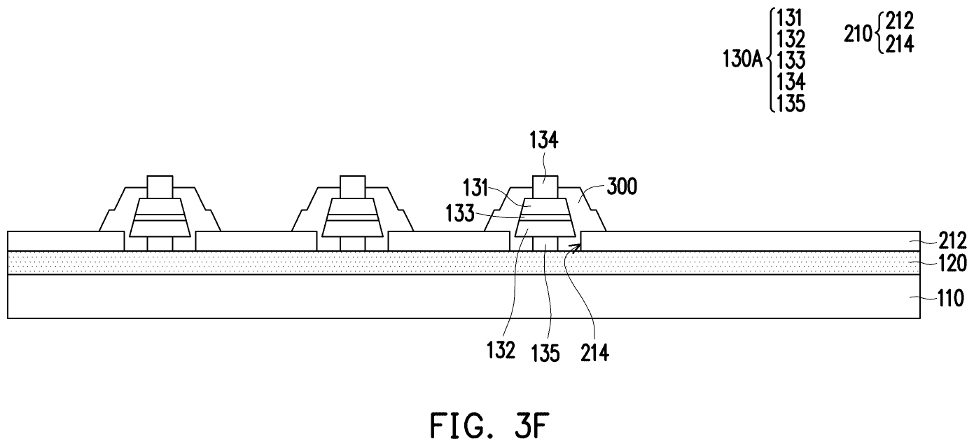

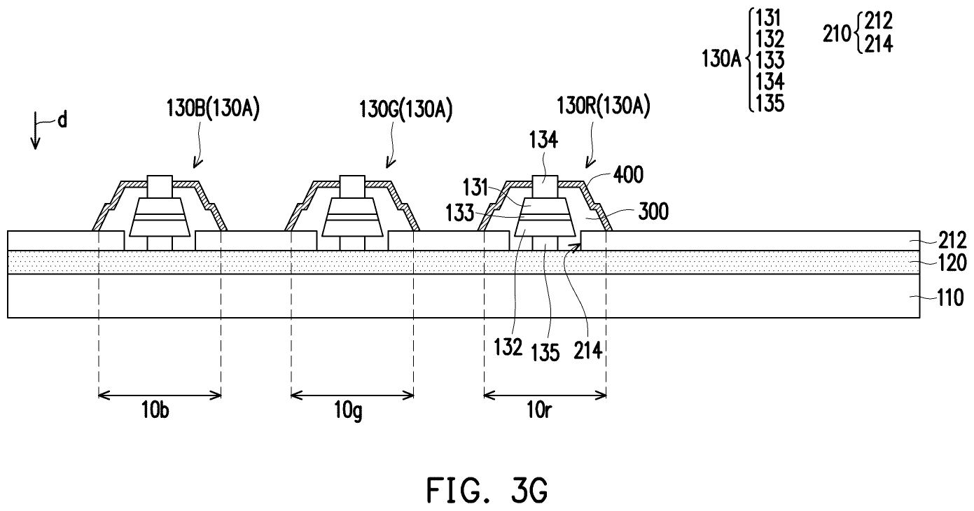

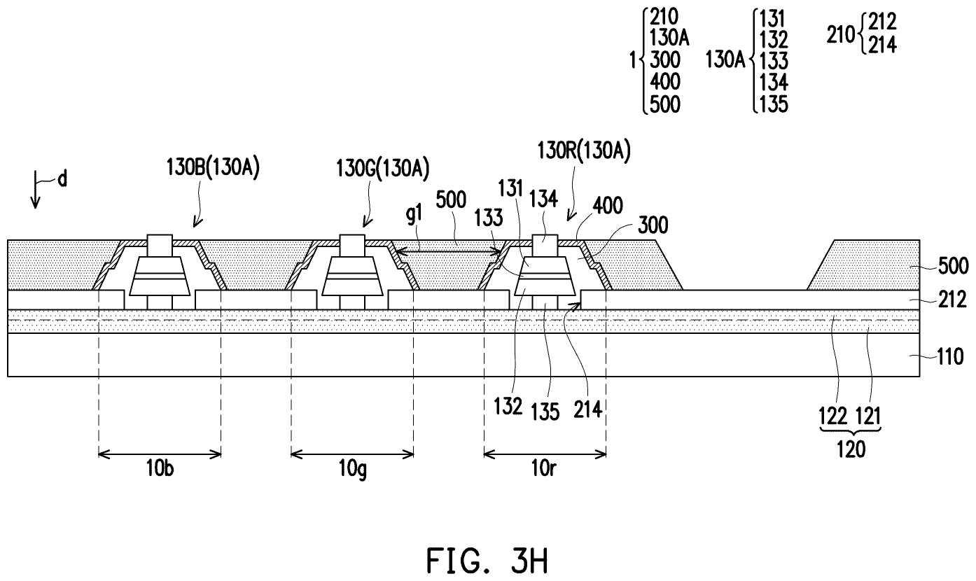

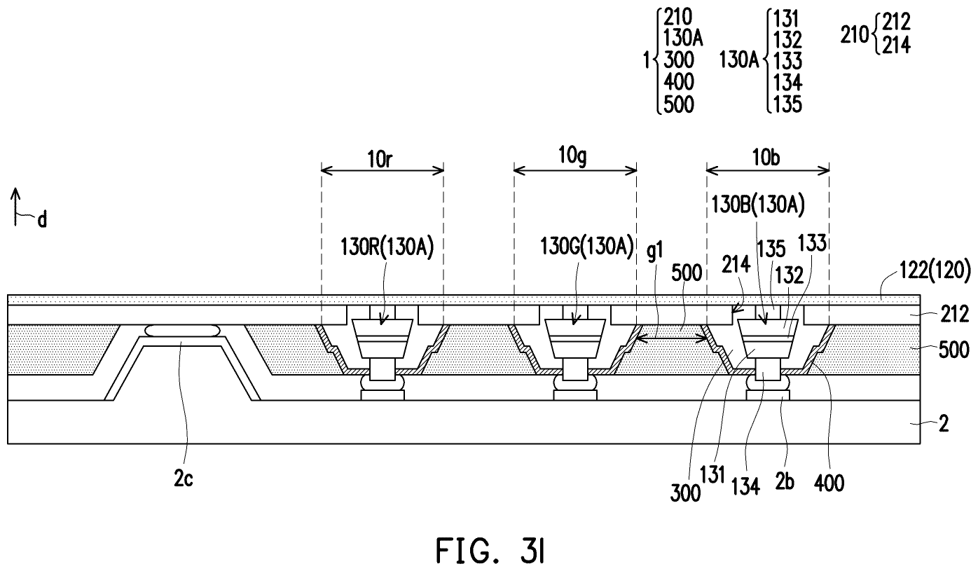

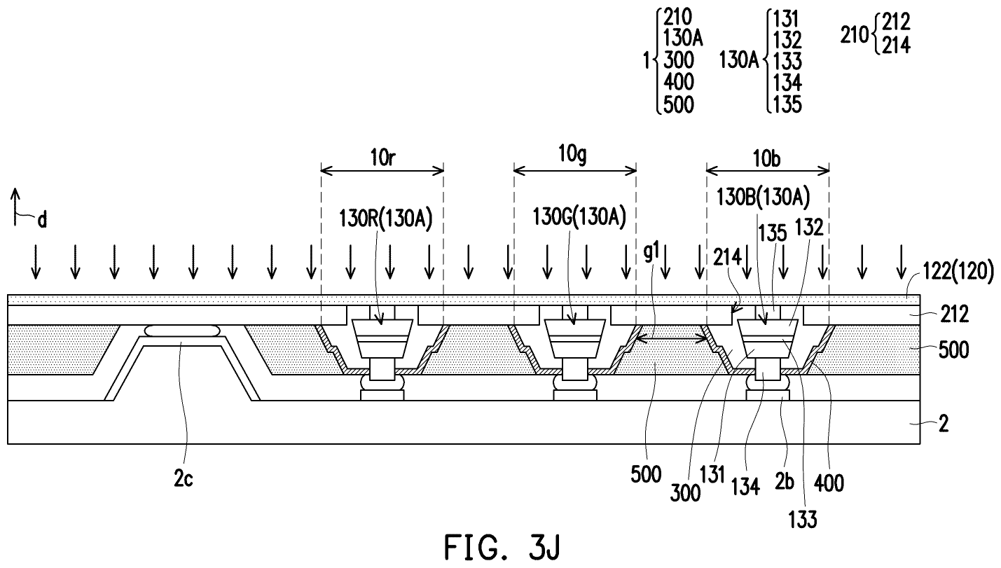

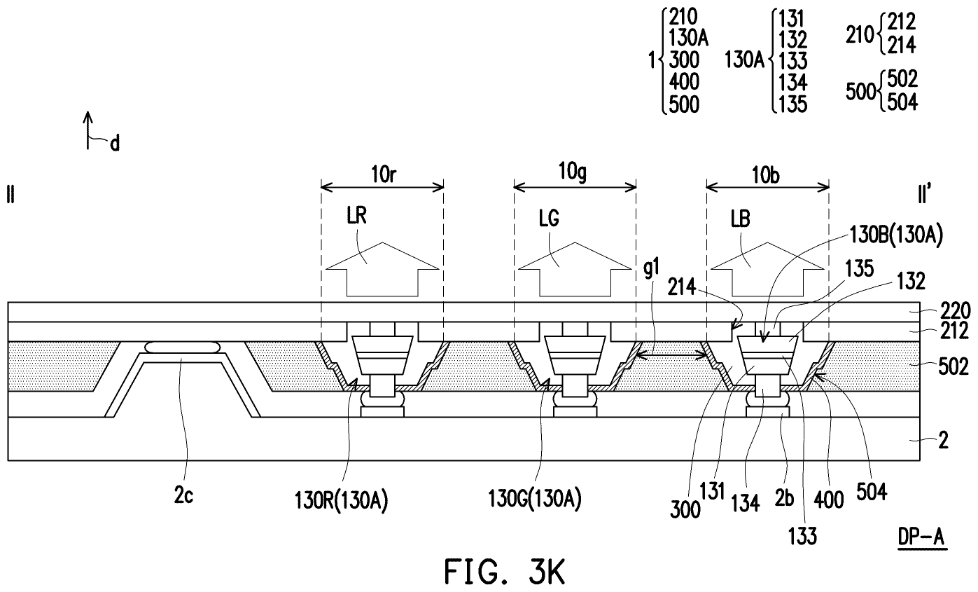

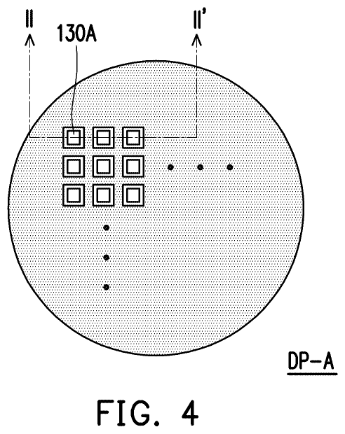

FIG. 3A to FIG. 3K are schematic cross-sectional views of the manufacturing process of the display apparatus according to an embodiment of the disclosure. FIG. 4 is a schematic top view of a display apparatus according to an embodiment of the disclosure. FIG. 3K corresponds to the section line II-II′ of FIG. 4.

The manufacturing process of the display apparatus DP-A in FIG. 3A to FIG. 3K is similar to the manufacturing process of the display apparatus DP in FIG. 1A to FIG. 1K. Regarding the manufacturing process of the display apparatus DP-A in FIG. 3A to FIG. 3K, please refer to FIG. 3A to FIG. 3K and the corresponding descriptions above, which will not be repeated here.

The display apparatus DP-A in FIG. 3K and FIG. 4 is similar to the display apparatus DP in FIG. 1K and FIG. 2. The difference between the two is that the light-emitting element 130A of the display apparatus DP-A is different from the light-emitting element 130 of the display apparatus DP.

Please refer to FIG. 3K and FIG. 4. Specifically, in this embodiment, the first electrode 134 and the second electrode 135 of each of light-emitting elements 130A are respectively located on opposite sides of the active layer 133. In the other word, the light-emitting element 130A is a vertical micro-light-emitting diode. In this embodiment, the electrodes of the light-emitting elements 130A bonded to the driving backplane 2 may be the first electrodes 134 of the light-emitting elements 130A, the first electrodes 134 of the light-emitting elements 130A are electrically connected to the bonding pads 2b of the driving backplane 2 respectively, the second electrodes 135 of the light emitting elements 130A may be electrically connected to the common electrode 2c of the driving backplane 2 through the transparent conductive layer 220 disposed on the transparent metal oxide pattern layer 210. In this embodiment, the transparent conductive layer 220 may include metal oxides, such as indium tin oxide, indium zinc oxide, aluminum tin oxide, aluminum zinc oxide, indium germanium zinc oxide, other suitable oxides or a stack of at least two of the above, but the disclosure is not limited to thereto.

It will be apparent to those skilled in the art that various modifications and variations can be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. A display apparatus comprising:
a driving backplane;
a transparent metal oxide pattern layer having a solid portion and openings defined by the solid portion;
a plurality of light-emitting elements respectively located in the openings of the transparent metal oxide pattern layer, wherein electrodes of the light-emitting elements are bonded to the driving backplane; and
a plurality of transparent structures respectively cover the light-emitting elements, respectively overlap the openings of the transparent metal oxide pattern layer, and respectively expose the electrodes of the light-emitting elements, wherein the transparent structures are located between the light-emitting elements and the driving backplane.

2. The display apparatus according to claim 1, further comprising:
a plurality of reflective patterns respectively disposed on the transparent structures and expose the electrodes of the light-emitting elements, wherein the reflective patterns are located between the transparent structures and the driving backplane.

3. The display apparatus according to claim 2, further comprising:
a light-shielding layer covering a gap between the reflective patterns, wherein the light-shielding layer is located between the transparent metal oxide pattern layer and the driving backplane.

4. The display apparatus according to claim 3, wherein the solid portion of the transparent metal oxide pattern layer has sidewalls defining the openings of the transparent metal oxide pattern layer, and there are gaps between the light-emitting elements and the sidewalls of the transparent metal oxide pattern layer, and the transparent structures fill in the gaps.

5. The display apparatus according to claim 3, wherein a maximum dimension of each of the transparent structures in a direction substantially parallel to the driving backplane is greater than a dimension of a corresponding opening of the openings of the transparent metal oxide pattern layer in the direction.

6. The display apparatus according to claim 3, wherein each of the reflective patterns at least partially overlaps a corresponding opening of the openings of the transparent metal oxide pattern.

7. The display apparatus according to claim 3, wherein the light-shielding layer is located between the reflective patterns and the driving backplane.

8. The display apparatus according to claim 3, wherein a solid portion of the light-shielding layer overlaps the solid portion of the transparent metal oxide pattern layer.

9. The display apparatus according to claim 3, wherein openings of the light-shielding layer respectively overlap with the openings of the transparent metal oxide pattern layer.

10. The display apparatus according to claim 1, wherein each of the light-emitting elements comprises a first semiconductor layer, a second semiconductor layer, an active layer disposed between the first semiconductor layer and the second semiconductor layer, and a first electrode and a second electrode electrically connected to the first semiconductor layer and the second semiconductor layer respectively, the first electrode and the second electrode are respectively located on opposite sides of the active layer; the electrodes of the light-emitting elements bonded to the driving backplane are first electrodes of the light-emitting elements; second electrodes of the light-emitting elements are electrically connected to the driving backplane through the transparent metal oxide pattern layer.

11. A manufacturing method of a display apparatus comprising:
providing a light-emitting element substrate, wherein the light-emitting element substrate comprises a temporary base, an adhesive layer, light-emitting elements and adhesive patterns, the adhesive layer is disposed on the temporary base, and the light-emitting elements are disposed on the adhesive layer, and the adhesive patterns are respectively disposed on the light-emitting elements;
forming a transparent metal oxide layer on the temporary base to cover the adhesive layer, the light-emitting elements and the adhesive patterns;
patterning the transparent metal oxide pattern layer to form a transparent metal oxide pattern layer, wherein a solid portion of the transparent metal oxide pattern layer covers a portion of the adhesive layer, and openings of the transparent metal oxide pattern layer respectively expose the adhesive patterns;
in a condition where the solid portion of the transparent metal oxide pattern layer covers the portion of the adhesive layer, removing the adhesive patterns on the light-emitting elements to expose electrodes of the light-emitting elements respectively located in the openings of the transparent metal oxide pattern layer;
forming transparent structures respectively on the light-emitting elements, wherein the transparent structures respectively cover the light-emitting elements, respectively overlap the openings of the transparent metal oxide pattern layer and expose the electrodes of the light-emitting elements, a light-emitting element array structure comprises the transparent metal oxide pattern layer, the light-emitting elements and the transparent structures;
separating at least one portion of the light-emitting element array structure and at least one portion of the adhesive layer; and
bonding the light-emitting element array structure to a driving backplane, wherein the electrodes of the light-emitting elements are electrically connected to the driving backplane.

12. The manufacturing method of the display apparatus according to claim 11, further comprising:
forming reflective patterns respectively on the transparent structures, wherein the reflective patterns are respectively disposed on the transparent structures and expose the electrodes of the light-emitting elements, and the light-emitting element array structure comprises the transparent metal oxide pattern layer, the light-emitting elements, the transparent structures and the reflective patterns.

13. The manufacturing method of the display apparatus according to claim 12, further comprising:
forming a light-shielding layer to cover a gap between the reflective patterns, wherein the light-emitting element array structure comprises the transparent metal oxide pattern layer, the light-emitting elements, the transparent structure, the reflective patterns and the light-shielding layer.

14. The manufacturing method of the display apparatus according to claim 13, wherein a step of separating the at least one portion of the light-emitting element array structure and the at least a portion of the adhesive layer comprising:
separating the light-emitting element array structure and a first part of the adhesive layer, wherein after the light-emitting element array structure is separated from the first part of the adhesive layer, a second part of the adhesive layer remains on the light-emitting elements and the transparent metal oxide pattern layer of the light-emitting element array structure.

15. The manufacturing method of the display apparatus according to claim 14, further comprising:
in a condition where the transparent metal oxide pattern layer shields the light-shielding layer, removing the second part of the adhesive layer on the light-emitting element array structure.
